(19) United States
(12) Patent Application Publication
(10) Pub. No.: US 2024/0178244 A1
(43) Pub. Date: May 30, 2024

(54) PHOTOELECTRIC CONVERSION APPARATUS AND DEVICE HAVING STACKED COMPONENTS

(71) Applicant: CANON KABUSHIKI KAISHA, Tokyo (JP)

(72) Inventor: HIROSHI SEKINE, Kanagawa (JP)

(21) Appl. No.: 18/523,353

(22) Filed: Nov. 29, 2023

(30) Foreign Application Priority Data
Nov. 30, 2022 (JP) 2022-190917

(51) Int. Cl. H01L 27/146

(52) U.S. Cl. CPC H01L 27/14612; H01L 27/14605; H01L 27/14623

(57) ABSTRACT

A photoelectric conversion apparatus includes first and second components. The first component includes a first semiconductor substrate (FSS), a first photoelectric conversion circuit (FPCC), a second photoelectric conversion circuit (SPCC), a floating diffusion, a first transfer transistor (FTT) that transfers signal charge generated in the FPCC to the FD, and a second transfer transistor (STT) that transfers signal charge generated in the SPCC to the floating diffusion. The second component includes a second semiconductor substrate, an insulator that penetrates through the second semiconductor substrate, a first amplification transistor that receives a signal via the FTT, and a second amplification transistor that receives a signal via the STT. The second component is stacked on the first component. A polysilicon member that is a gate of the FTT is a gate of the STT, and a through-electrode that penetrates through the insulator and the polysilicon member are electrically connected to each other.

### BACKGROUND

### Technical Field

The present disclosure relates to a photoelectric conversion apparatus and device.

### Description of the Related Art

Japanese Patent Laid-Open No. 2018/113606 discloses a photoelectric conversion apparatus constituted by semiconductor substrates stacked in three layers.

In Japanese Patent Laid-Open No. 2018/113606, a through-electrode is provided in an insulating region that penetrates through a second substrate, so that the area of the second substrate where elements can be arranged is limited.

### SUMMARY

An aspect of the present disclosure is a photoelectric conversion apparatus including a first component and a second component. The first component includes a first semiconductor substrate, a first photoelectric conversion circuit, a second photoelectric conversion circuit, a floating diffusion, a first transfer transistor, and a second transfer transistor. The first semiconductor substrate has a first plane and a second plane facing the first plane. The first photoelectric conversion circuit is configured to receive light from the second plane. The second photoelectric conversion circuit is configured to receive light from the second plane. The first transfer transistor is provided on a side where the first plane is provided and is configured to transfer signal charge generated in the first photoelectric conversion circuit to the floating diffusion. The second transfer transistor is provided on the side where the first plane is provided and is configured to transfer signal charge generated in the second photoelectric conversion circuit to the floating diffusion. The second component includes a second semiconductor substrate, an insulator, a first amplification transistor, and a second amplification transistor. The second semiconductor substrate has a third plane and a fourth plane facing the third plane. The insulator is configured to penetrate through the second semiconductor substrate from the third plane to the fourth plane or from the fourth plane to the third plane. The first amplification transistor is configured to receive a signal via the first transfer transistor. The second amplification transistor is configured to receive a signal via the second transfer transistor. The second component is stacked on the first component. A polysilicon member that is a gate of the first transfer transistor is a gate of the second transfer transistor, and a through-electrode configured to penetrate through the insulator and the polysilicon member are electrically connected to each other.

Further features of the disclosure will become apparent from the following description of exemplary embodiments with reference to the attached drawings.

### BRIEF DESCRIPTION OF THE DRAWINGS

FIG. 1 is a diagram illustrating the configuration of a photoelectric conversion apparatus according to an embodiment.

FIG. 2 illustrates an example of the arrangement of a sensor substrate of the photoelectric conversion apparatus according to the embodiment.

FIG. 3 illustrates an example of the arrangement of a circuit substrate of the photoelectric conversion apparatus according to the embodiment.

FIG. 4 is a block diagram including an equivalent circuit of a photoelectric conversion element of the photoelectric conversion apparatus according to a first embodiment.

FIGS. 5A and 5B are plan views of the photoelectric conversion apparatus according to the first embodiment.

FIG. 6 is a cross-sectional view of the photoelectric conversion apparatus according to the first embodiment.

FIG. 7 is a block diagram including an equivalent circuit of a photoelectric conversion element of a photoelectric conversion apparatus according to a second embodiment.

FIGS. 8A and 8B are plan views of the photoelectric conversion apparatus according to the second embodiment.

FIG. 9 is a cross-sectional view of the photoelectric conversion apparatus according to the second embodiment.

FIGS. 10A and 10B are plan views of a modification example of the photoelectric conversion apparatus according to the second embodiment.

FIG. 11 illustrates an equivalent circuit of a photoelectric conversion element of a photoelectric conversion apparatus according to a third embodiment.

FIGS. 12A and 12B are plan views of the photoelectric conversion apparatus according to the third embodiment.

FIG. 13 is a cross-sectional view of the photoelectric conversion apparatus according to the third embodiment.

FIG. 14 is a diagram illustrating the structure of a charge holding unit of the photoelectric conversion apparatus according to the third embodiment.

FIG. 15 is a diagram illustrating the structure of a modification example of the charge holding unit of the photoelectric conversion apparatus according to the third embodiment.

FIG. 16 illustrates a modification example of an equivalent circuit of the photoelectric conversion element of the photoelectric conversion apparatus according to the third embodiment.

FIG. 17 illustrates a modification example of an equivalent circuit of the photoelectric conversion element of the photoelectric conversion apparatus according to the third embodiment.

FIG. 18 is a plan view of a modification example of photoelectric conversion elements of the photoelectric conversion apparatus according to the third embodiment.

FIG. 19 is a diagram illustrating the configuration of a photoelectric conversion apparatus according to a fourth embodiment.

FIG. 20 illustrates an example of the arrangement of a sensor substrate of the photoelectric conversion apparatus according to the fourth embodiment.

FIG. 21 illustrates an example of the arrangement of a circuit substrate of the photoelectric conversion apparatus according to the fourth embodiment.

FIG. 22 illustrates an example of the arrangement of another circuit substrate of the photoelectric conversion apparatus according to the fourth embodiment.

FIG. 23 illustrates an equivalent circuit of photoelectric conversion elements of the photoelectric conversion apparatus according to the fourth embodiment.

FIGS. 24A, 24B, and 24C are plan views of the photoelectric conversion apparatus according to the fourth embodiment.

FIG. 25 is a cross-sectional view of the photoelectric conversion apparatus according to the fourth embodiment.

FIG. 26 is a cross-sectional view of a modification example of the photoelectric conversion apparatus according to the fourth embodiment.

FIG. 27 illustrates a modification example of an equivalent circuit of photoelectric conversion elements of the photoelectric conversion apparatus according to the fourth embodiment.

FIG. 28 is a block diagram including a modification example of an equivalent circuit of photoelectric conversion elements of the photoelectric conversion apparatus according to the fourth embodiment.

FIGS. 29A, 29B, and 23C are plan views of a modification example of the photoelectric conversion apparatus according to the fourth embodiment.

FIG. 30 is a functional block diagram of a photoelectric conversion system according to a fifth embodiment.

FIGS. 31A and 31B are functional block diagrams of a photoelectric conversion system according to a sixth embodiment.

FIG. 32 is a functional block diagram of a photoelectric conversion system according to a seventh embodiment.

FIG. 33 is a functional block diagram of a photoelectric conversion system according to an eighth embodiment.

FIGS. 34A and 34B are functional block diagrams of a photoelectric conversion system according to a ninth embodiment.

### DESCRIPTION OF THE EMBODIMENTS

In the following, each embodiment is described with reference to the drawings.

In each of the following embodiments, an image pickup apparatus will be focused on as an example of a photoelectric conversion apparatus. Note that the individual embodiments are not limited to image pickup apparatuses and can be applied to other examples of photoelectric conversion apparatuses. For example, there are distance measuring devices (devices for, for example, distance measurement using focus detection and Time of Flight (TOF)) and light metering devices (devices for, for example, measuring the amount of incident light).

The conductivity types of semiconductor regions and wells and dopants injected in the embodiments described below are examples, and are not limited to only the conductivity types and dopants described in the embodiments. The conductivity types and dopants described in the embodiments can be changed as needed, and the potentials of the semiconductor regions and wells are changed as needed accordingly with this change.

Note that the conductivity types of the transistors described in the following embodiments are examples and are not limited to only the conductivity types described in the exemplary embodiments. The conductivity type of each transistor described in the embodiments can be changed as needed, and the gate, source, and drain potentials of the transistor are changed accordingly with this change.

For example, for a transistor to operate as a switch, it is sufficient that the low and high levels of the potential supplied to the gate be switched as the conductivity type is changed, in contrast to description in the exemplary embodiment. The conductivity types of semiconductor regions described in the following exemplary embodiments are also examples, and are not limited to only the conductivity types described in the exemplary embodiments. The conductivity types described in the exemplary embodiments can be changed as needed, and the potentials of semiconductor regions can be changed accordingly with this change.

In the following embodiments, connections between circuit elements may also be mentioned. In this case, even in a case where there is another element between elements of interest, the elements of interest are treated as connected, unless otherwise noted. For example, suppose that an element A is connected to one node of a capacitive element C having a plurality of nodes, and an element B is connected to another node of the capacitive element C. Even in such a case, the elements A and B are treated as connected, unless otherwise noted.

Metal members such as wiring lines and pads described herein may be composed of a single metal of one element or a mixture (an alloy). For example, wiring lines described as copper wiring lines may be composed of copper alone or may be composed primarily of copper with additional other components. For example, pads that are connected to external terminals may be composed of aluminum alone or may be composed primarily of aluminum with additional other components. The copper wiring lines and aluminum pads described here are examples and can be changed to various metals.

The wiring lines and pads described here are examples of metal members used in photoelectric conversion apparatuses and may be applicable to other metal members.

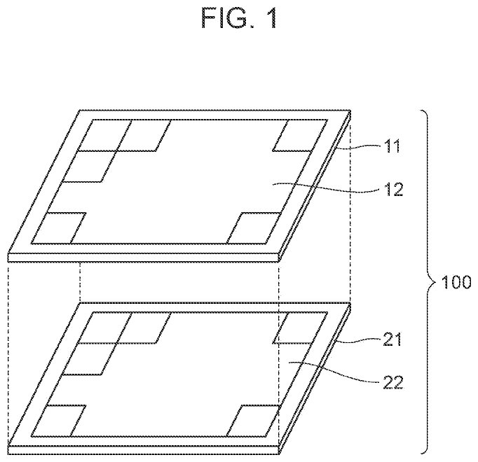

The configuration common to each embodiment of a photoelectric conversion apparatus, which is an example of a semiconductor device according to the present disclosure, will be described using FIGS. 1 to 3.

FIG. 1 is a diagram illustrating the configuration of a photoelectric conversion apparatus 100 of a multilayer type according to an embodiment of the present disclosure.

The photoelectric conversion apparatus 100 includes two substrates which are stacked one on top of the other and are electrically connected to each other. The two substrates are a sensor substrate 11 and a circuit substrate 21. The sensor substrate 11 has a first semiconductor layer (a first semiconductor substrate) and a first wiring layer. The first semiconductor layer has photoelectric conversion elements 102, which will be described later. The circuit substrate 21 has a second semiconductor layer (a second semiconductor substrate) and a second wiring layer. The second semiconductor layer has, for example, signal processing units 103, which will be described later. In the photoelectric conversion apparatus described in each embodiment, the surface of a first semiconductor layer 300 that is in contact with a first wiring layer 301 is called the front surface (a first plane) of the first semiconductor layer 300, and the surface of the first semiconductor layer 300 facing the front surface of the first semiconductor layer 300 is called the rear surface (a second plane) of the first semiconductor layer 300. Similarly, the surface of a second semiconductor layer 400 that is in contact with a second wiring layer 401 is called the front surface (a third plane) of the second semiconductor layer 400, and the surface of the second semiconductor layer 400 on the opposite side from the third plane is called the rear surface (a fourth plane) of the second semiconductor layer 400. In the following, the sensor substrate 11 and the circuit substrate 21 will be described as chips obtained by dicing; however, the sensor substrate 11 and the circuit substrate 21 are not limited to such chips. For example, each substrate may be a wafer. The individual substrates may be stacked one on top of the other in a wafer state and then be subjected to dicing. Alternatively, the individual substrates may be divided into chips, and chips may be staked one on top of the other and joined to each other.

A pixel region 12 is arranged on the sensor substrate 11, and a circuit region 22, which processes signals detected by the pixel region 12, is arranged on the circuit substrate 21.

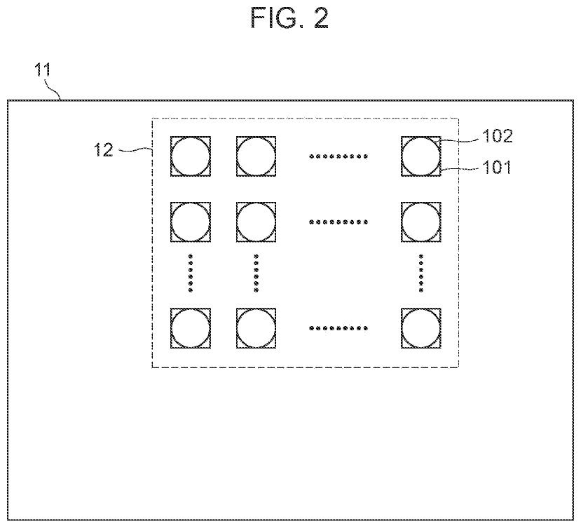

FIG. 2 is a diagram illustrating an example of the arrangement of the sensor substrate 11. The pixel region 12 is formed by arranging, in a two-dimensional array in a plan view, pixels 101 having photoelectric conversion elements 102.

Typically, the pixels 101 are pixels for forming an image; however, the pixels 101 do not have to form an image when used for time of flight (TOF). That is, the pixels 101 may also be used to measure the time of arrival of light and the amount of light.

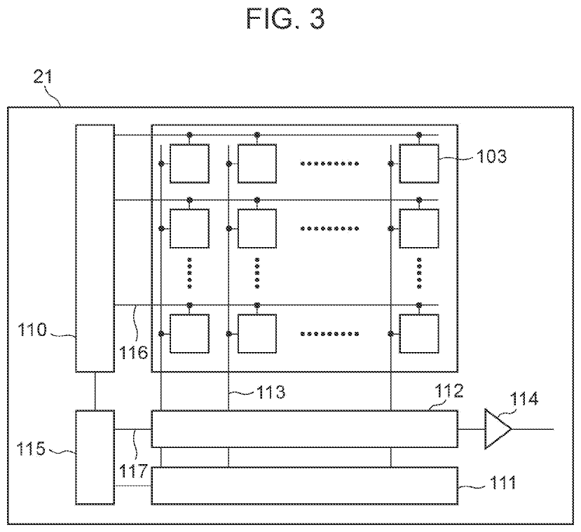

FIG. 3 is a diagram of the configuration of the circuit substrate 21. The circuit substrate 21 has signal processing units 103, a read-out circuit 112 (the column circuit 112), a control pulse generation unit 115, a horizontal scanning circuit 111, signal lines 113, and a vertical scanning circuit 110. The signal processing units 103 process electric charge obtained by photoelectric conversion performed by the photoelectric conversion elements 102 in FIG. 2.

The photoelectric conversion elements 102 in FIG. 2 are electrically connected to the signal processing units 103 in FIG. 3 via connection wiring lines provided on a pixel basis.

The vertical scanning circuit 110 receives a control pulse supplied from the control pulse generation unit 115 and supplies the control pulse to each pixel. In the vertical scanning circuit 110, a logic circuit such as a shift register or an address decoder is used.

In each pixel 101, a signal output from the photoelectric conversion element 102 is processed by the signal processing unit 103. The signal processing unit 103 is provided with a reset transistor, an amplification transistor, a memory, and so forth described below.

To read out signals from the individual pixels, the horizontal scanning circuit 111 inputs, into the signal processing units 103, a control pulse for sequentially selecting a column.

Regarding a selected column, a signal is output from the signal processing unit 103 of the pixel selected by the vertical scanning circuit 110 to a corresponding one of the signal lines 113.

The signal output to the signal line 113 is output through an output circuit 114 to a recording unit or a signal processing unit outside the photoelectric conversion apparatus 100.

In FIG. 2, the photoelectric conversion elements 102 in the pixel region 12 may be arranged in a one-dimensional shape. In addition, it is also possible to obtain the effects of the present disclosure even if there is only one pixel, and the case of a single pixel is also included in the present disclosure. Each of the photoelectric conversion elements 102 does not always need to have the function of the signal processing unit 103. For example, one signal processing unit 103 may be shared by a plurality of photoelectric conversion elements 102, and signal processing may be sequentially performed for the plurality of photoelectric conversion elements 102.

As illustrated in FIGS. 2 and 3, the signal processing units 103 are arranged in a region that overlaps the pixel region 12 in a plan view. The vertical scanning circuit 110, the horizontal scanning circuit 111, the column circuit 112, the output circuit 114, and the control pulse generation unit 115 are arranged so as to overlap a region between the ends of the sensor substrate 11 and the ends of the pixel region 12 in a plan view. In other words, the sensor substrate 11 includes the pixel region 12 and a non-pixel region surrounding the pixel region 12. The vertical scanning circuit 110, the horizontal scanning circuit 111, the column circuit 112, the output circuit 114, and the control pulse generation unit 115 are arranged in a region that overlaps the non-pixel region in a plan view.

Note that the arrangement of the signal lines 113, the column circuit 112, and the output circuit 114 is not limited to the arrangement illustrated in FIG. 3. For example, the signal lines 113 may be arranged so as to extend in the row direction, and the column circuit 112 may be arranged at a position beyond the signal lines 113 and in the direction in which the signal lines 113 extend.

In the following, photoelectric conversion apparatuses according to the individual embodiments will be described. Note that the sensor substrate 11 described above may also be called a first substrate or a first component, and the circuit substrate 21 described above may also be called a second substrate or a second component. Moreover, the rear surface side of the first semiconductor layer defined above may also be called a light-incident side.

### First Embodiment

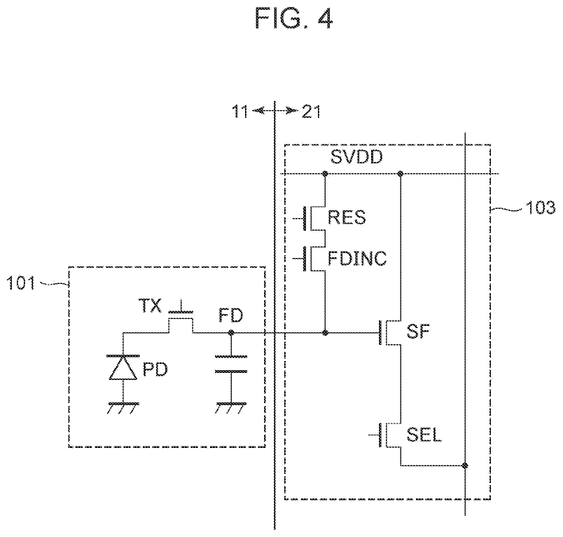

In the following, each embodiment is described with reference to the drawings. FIG. 4 is an example of a block diagram including equivalent circuits of FIGS. 2 and 3.

FIG. 4 illustrates an example of the configuration of each pixel 101. Examples of the photoelectric conversion element 102 and the signal processing unit 103 are illustrated.

Each pixel 101 has, for example, a photodiode PD, a transfer transistor TX electrically connected to the photodiode PD, and a floating diffusion FD. The signal processing unit 103 temporarily holds, in the floating diffusion FD, electric charge output from the photodiode PD via the transfer transistor TX. The floating diffusion FD is connected to an input node of an amplification transistor AMP. The photodiode PD performs photoelectric conversion to generate electric charge corresponding to the amount of light received. The cathode of the photodiode PD is electrically connected to the source of the transfer transistor TX, and an electric potential applied to the well region is applied to the anode of the photodiode PD.

That is, the anode of the photodiode PD is electrically connected to a reference potential line (for example, ground potential). Moreover, the photodiode PD is provided in the well region connected to this reference potential line. The drain of the transfer transistor TX is electrically connected to the floating diffusion FD, and the gate of the transfer transistor TX is electrically connected to a pixel drive line. The transfer transistor TX is, for example, a complementary metal-oxide-semiconductor (CMOS) transistor.

The signal processing unit 103 includes, for example, a reset transistor RES, a selection transistor SEL, and an amplification transistor SF. Note that the selection transistor SEL may be omitted as needed. Moreover, the electrical path between the reset transistor RES and the floating diffusion FD may be further equipped with a transistor FDINC to change the capacitance value of the floating diffusion FD.

The source of the reset transistor RES (the input terminal of the signal processing unit 103) is electrically connected to the floating diffusion FD. The drain of the reset transistor RES is electrically connected to a power supply line (SVDD) and the drain of the amplification transistor SF. The gate of the reset transistor RES is electrically connected to the pixel drive line. The source of the amplification transistor SF is electrically connected to the drain of the selection transistor SEL, and the gate of the amplification transistor SF is electrically connected to the source of the reset transistor RES. The source of the selection transistor SEL (the output terminal of the signal processor 103) is electrically connected to a pixel output line, and the gate of the selection transistor SEL is electrically connected to the pixel drive line.

When the transfer transistor TX enters its ON state, the electric charge of the photodiode PD is transferred to the floating diffusion FD. The reset transistor RES resets the electric potential of the floating diffusion FD to a predetermined potential. When the reset transistor RES enters its ON state, the electric potential of the floating diffusion FD is reset to the electric potential of the power supply line (SVDD). The selection transistor SEL controls the output timing of a pixel signal from the signal processing unit 103. The amplification transistor SF generates, as a pixel signal, a voltage signal corresponding to the level of the electric charge held in the floating diffusion FD. The amplification transistor SF constitutes a source follower type amplifier, which outputs a pixel signal that is a voltage signal corresponding to the level of electric charge generated by the photodiode PD. When the selection transistor SEL enters its ON state, the amplification transistor SF amplifies the electric potential of the floating diffusion FD and outputs a voltage corresponding to the resulting electric potential to a column signal processing circuit via the pixel output line. The reset transistor RES, the amplification transistor SF, and the selection transistor SEL are CMOS transistors, for example.

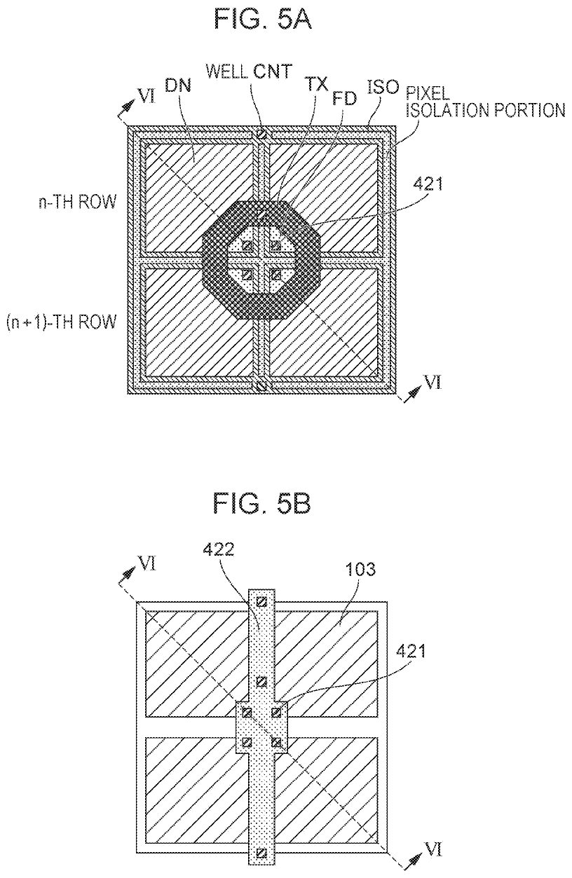

FIGS. 5A and 5B are plan views of a photoelectric conversion apparatus according to the present embodiment. FIG. 5A illustrates a plan view of the first substrate, and FIG. 5B illustrates a plan view of the second substrate.

FIG. 5A illustrates four pixels 101 arranged in two rows and two columns among the pixels 101 arranged in or on the first substrate. Each of the photodiodes PD of the four pixels 101 is connected to its corresponding floating diffusion FD via its corresponding through-via 421. Consider a case where, among the four pixels 101 arranged in two rows and two columns, one of the photodiodes PD arranged in the n-th row of the pixel array is called a first photoelectric conversion unit and the other is called a second photoelectric conversion unit. In this case, the signal charge generated in the first photoelectric conversion unit is transferred to a first floating diffusion FD by a first transfer transistor and is input to the gate of a first amplification transistor SF. The signal charge generated in the second photoelectric conversion unit is transferred to a second floating diffusion FD by a second transfer transistor and is input to the gate of a second amplification transistor SF. DN illustrated in FIG. 5A denotes a semiconductor region included in each photodiode PD. The four pixels 101 share the gate of one transfer transistor TX. The gate of the transfer transistor TX is a polysilicon member that is provided on the first semiconductor layer and to which the through-vias 421 are connected. That is, this polysilicon member is the gate of the first transfer transistor and also the gate of the second transfer transistor. A well contact is provided in the well area of the first substrate to supply a predetermined potential (typically, ground potential) from the second substrate via the through-via 421.

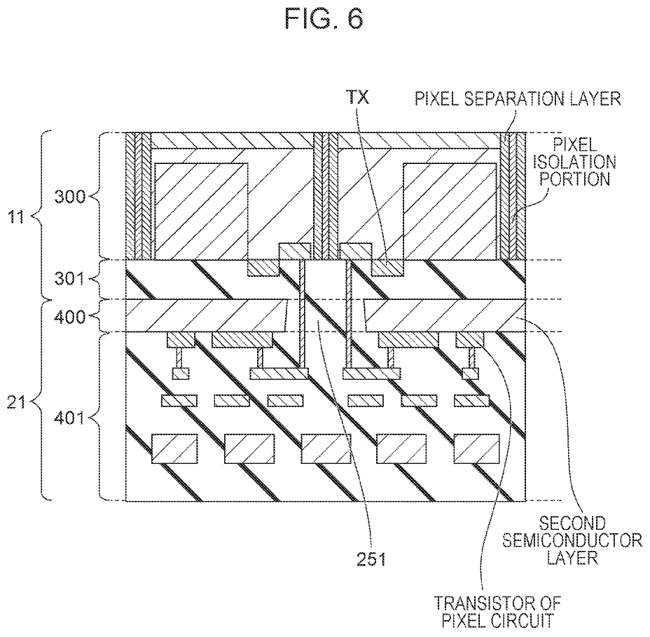

FIG. 6 is a cross-sectional view of the photoelectric conversion apparatus according to the present embodiment. This cross-sectional view illustrates a cross section taken along VI-VI of FIGS. 5A and 5B. A first semiconductor region 300 has photodiodes PD. That is, the semiconductor region 300 includes a photoelectric conversion region DN that generates and accumulates signal charge (electrons in the present embodiment) corresponding to incident light. The semiconductor region DN is an N-type impurity region. FIG. 5A illustrates a configuration in which the four pixels 101 are connected to four floating diffusions FD with one transfer transistor TX interposed therebetween. This cross-sectional view in FIG. 6 illustrates two pixels 101 appearing in one cross-section among the four pixels 101.

The transfer gate of the transfer transistor TX controls conduction between the photodiode PD and the floating diffusion FD of each pixel. A pixel isolation portion 201 is provided between a plurality of pixels 101 and electrically separates a plurality of semiconductor regions from each other. The pixel isolation portion 201 may include an insulating section such as silicon oxide or may be a semiconductor region that forms a potential barrier. Typically, the pixel isolation portion 201 is a semiconductor region whose primary carrier is a charge having polarity opposite to that of signal charge accumulated by the photodiode PD. A pixel separation layer is provided between the pixel isolation portion 201 and the photodiode PD. The pixel separation layer has the role of reducing dark current, especially when the pixel isolation portion 201 including an insulating section is provided. The floating diffusion FD and the gate of the amplification transistor SF are connected with a through-hole electrode interposed therebetween. The through-hole electrode is composed mainly of metals such as tungsten and copper. The through-hole electrode is formed so as to penetrate through an insulator 251 that separates the second semiconductor layer 400. The insulator 251 electrically separates the plurality of signal processing units 103 from each other. The insulator 251 is provided so as to penetrate through the second semiconductor layer 400 from the third plane to the fourth plane thereof.

The transfer transistors TX are scanned in row order for the pixels 101 arranged in an array in the pixel region 12. In the photoelectric conversion apparatus having a configuration illustrated in FIGS. 5A to 6, electric charge is simultaneously transferred to the floating diffusion FD connected to each photodiode PD in each of the pixels 101 arranged in the n-th row and the (n+1)-th row in the pixel array. Separate signal processing units 103 are independently provided for the floating diffusions FD of the respective pixels 101, and signals of the floating diffusions FD of all the pixels 101 are read out via the signal lines, column circuit, and output circuit during one scanning period.

### Second Embodiment

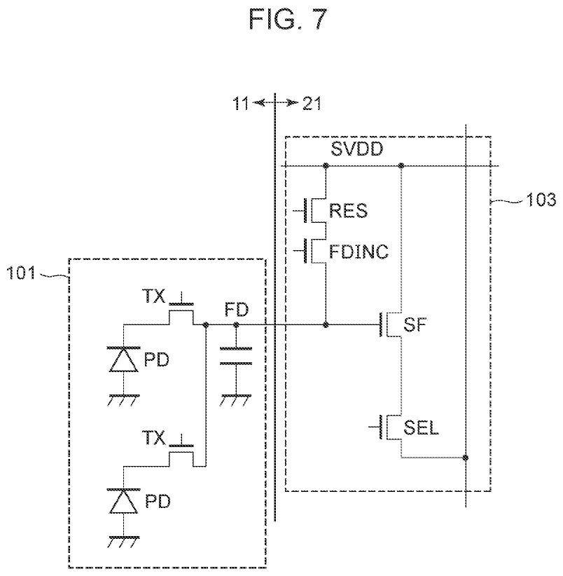

A photoelectric conversion apparatus according to the present embodiment will be described using FIGS. 7 to 10B. Description common to the first embodiment will be omitted, and points that differ from the first embodiment will be mainly described.

FIG. 7 illustrates an example of a pixel 101 of a photoelectric conversion apparatus according to the present embodiment. The second embodiment differs from the first embodiment in that two photodiodes PD are connected to one signal processing unit 103 with one floating diffusion FD interposed therebetween.

Similarly to as in the first embodiment, photodiodes PD, transfer transistors TX, and floating diffusions FD are provided in or on the first substrate. Elements such as reset transistors RES and selection transistors SEL, control lines, and signal lines are arranged in or on the second substrate.

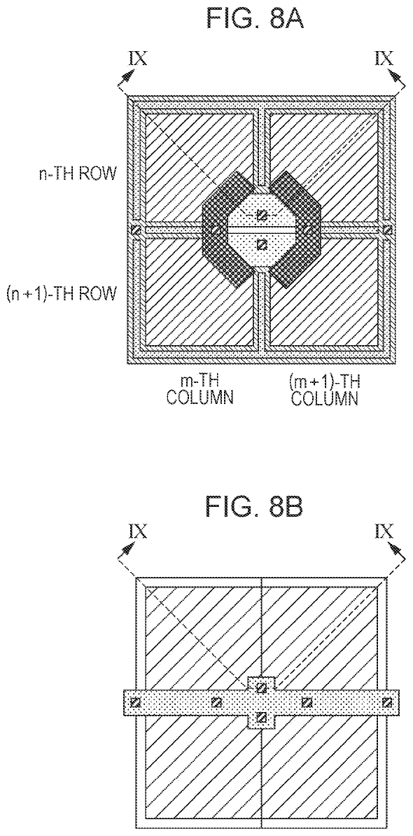

FIGS. 8A and 8B are plan views of the photoelectric conversion apparatus according to the present embodiment. FIG. 8A illustrates a plan view of the first substrate, and FIG. 8B illustrates a plan view of the second substrate.

FIG. 8A illustrates four pixels 101 arranged in two rows and two columns among the pixels 101 arranged in or on the first substrate. Among the four pixels 101, two pixels 101 arranged in the same row are connected to one floating diffusion FD via a common through-via 421. Moreover, among the four pixels 101, the two pixels 101 arranged in the same column share the gate of one transfer transistor TX. Each transfer transistor TX has one through-via 421.

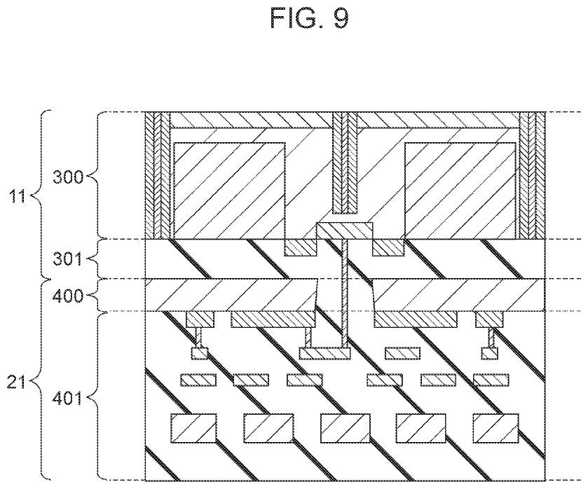

FIG. 9 is a cross-sectional view of the photoelectric conversion apparatus according to the present embodiment. This cross-sectional view illustrates a cross section taken along IX-IX of FIGS. 8A and 8B. The first and second substrates are electrically connected to each other by the through-via 421.

A feature of the photoelectric conversion apparatus according to the present embodiment is that the pixels 101 that do not share the gate of any transfer transistor TX among the four pixels 101 arranged in two rows and two columns share a floating diffusion FD. By combining sharing of the gate of the transfer transistor TX and sharing of the floating diffusion FD, it is possible to reduce the number of through-electrodes 421 compared to that in the first embodiment. In addition, the number of circuits arranged in or on the second substrate can be reduced by sharing a signal processing section 103 among a plurality of pixels 101. Thus, noise performance can be improved by increasing the ratio (L/W) of channel width (W) to channel length (L) of the amplification transistor SF, for example.

In the photoelectric conversion apparatus according to the present embodiment, the transfer transistors are controlled every two rows in the order of an even-numbered row (the m-th column) and an odd-numbered row (the (m+1)-th column). First, electric charge is transferred to each FD in the n-th and (n+1)-th rows simultaneously. Specifically, first, the transfer transistors spanning the n-th and (n+1)-th rows and arranged in the even-numbered column are turned on. Then, a signal at (n, m) is transferred to the floating diffusion FD arranged in the n-th row. At the same time, a signal at (n+1, m) is transferred to the floating diffusion FD arranged in the (n+1)-th row.

Since a pixel circuit is independently provided for each floating diffusion FD, signals from all the floating diffusions FD are read out via the signal lines, column circuit, and output circuit during one scanning period. Next, the transfer transistors spanning the n-th and (n+1)-th rows and arranged in the odd-numbered column are turned on. The subsequent procedure is the same as the operation described above.

In other words, a first group of transfer transistors including the transfer transistors corresponding to the pixels 101 at (n, m) and (n+1, m) is controlled by a first control signal. A second group of transfer transistors including the transfer transistors corresponding to the pixels 101 at (n, m+1) and (n+1, m+1) is also controlled by the first control signal. Note that the way in which driving is performed is not limited to this, and scanning may be performed sequentially in the column direction, for example. In this case, the direction in which the transfer transistors included in the first group of transfer transistors are arranged (vertical direction) intersects with the direction in which the floating diffusions FD connected to each of the transfer transistors included in the first group of transfer transistors is arranged (horizontal direction).

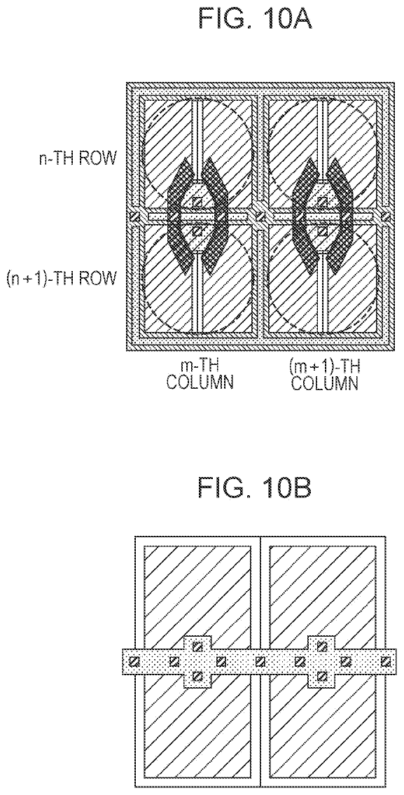

FIGS. 10A and 10B are modification examples of the plan views of the photoelectric conversion apparatus according to the present embodiment. FIG. 10A illustrates a plan view of the first substrate, and FIG. 10B illustrates a plan view of the second substrate.

FIG. 10A illustrates four pixels 101 arranged in two rows and two columns among the pixels 101 arranged in or on the first substrate. Each pixel 101 has two photodiodes PD arranged in one of multiple layers (ML). The two photodiodes PD of each pixel 101 are used for image plane phase difference AF (DAF). One of the two photodiodes PD may be used for SAF by shielding the other one of the two photodiodes PD from light. Among the four pixels 101, the two pixels 101 arranged in the same row are connected to one floating diffusion FD via a common through-via 421. Moreover, among the four pixels 101, the two pixels 101 arranged in the same column share the gate of one transfer transistor TX. Each transfer transistor TX has one through-via 421.

Electric charge is transferred at the same timing as in the case of the structure illustrated in FIGS. 8A and 8B. However, since each pixel 101 illustrated in FIG. 10A has two photodiodes PD, driving is thus different from that for the photoelectric conversion apparatus whose configuration is illustrated in FIGS. 8A and 8B in that three readout operations including readout of a noise signal (N signal) are performed during one readout period. Suppose that a signal read out from one of the two photodiodes PD is an A signal and a signal read out from the other photodiode PD is a B signal. In this case, in one readout period, three readout operations are performed such that the N signal is read out, the A signal is read out, and the A+B signals are read out.

### Third Embodiment

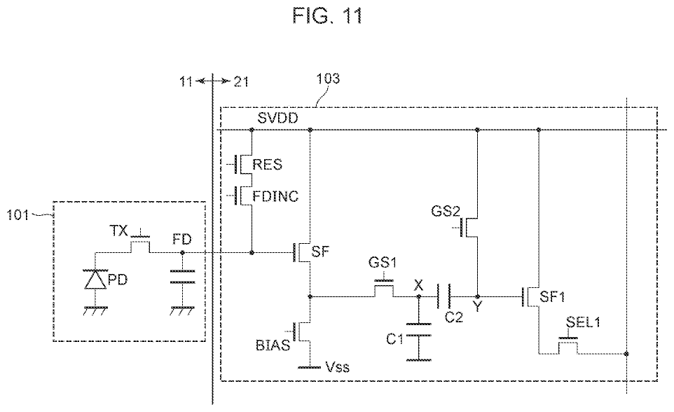

A photoelectric conversion apparatus according to the present embodiment will be described using FIGS. 11 to 18. Description common to the first embodiment will be omitted, and points that differ from the first embodiment will be mainly described.

FIG. 11 illustrates an example of a pixel 101 of the photoelectric conversion apparatus according to the present embodiment. The third embodiment differs from the first embodiment in that memories C1 and C2, which hold outputs from the amplification transistor SF, are provided in the stage after the amplification transistor SF. The output terminal of the amplification transistor SF is connected to a node with a transistor GS1 interposed therebetween, the node having the memory C1. The transistor GS1 is for writing signals to the memories C1 of a plurality of pixels 101 at once. The transistor GS1 is connected to the gate of an amplification transistor SF1 with the memory C2 interposed therebetween. The memory C2 and a transistor GS2 are provided between the transistor GS1 and the wiring line supplying the power supply voltage SVDD. The transistor GS2, when turned on, resets the electric potential between the memory C2 and the amplification transistor SF1 collectively.

A current source transistor BIAS, which functions as a constant current source, is connected between the output terminal of the amplification transistor SF and a reference potential Vss. When the current source transistor BIAS is to function as a constant current source, a predetermined level of voltage is applied. When the current source transistor BIAS is not to function as a constant current source (not used), a Low level (0 V) is applied. Although a constant current source is not an essential constructional element, the configuration including a constant current source increases the speed of writing into memories.

In the circuit configuration according to the present embodiment, for example, the following driving is assumed.

First, the reset transistor RES and the transfer transistor TX are turned on to reset the photodiode PD and start electric charge accumulation. During the electric charge accumulation period, the reset transistor RES and the transistor GS2 are turned on to reset the potentials of the floating diffusion FD, a node X, and a node Y.

Next, after a reset settling period, the transfer transistor TX is turned on, and a signal is transferred from the photodiode PD to the floating diffusion FD. In this case, the transistor GS1 is also turned on. The voltage level of the output from the amplification transistor SF is written to the node X through the transistor GS1, and voltage is also written to the node Y through capacitive coupling.

Signals of the nodes Y are sequentially read out in row order by operating selection transistors SEL1. The read-out signals are AD-converted by the column ADC in the subsequent stage.

Thereafter, the transistor GS2 is turned on to reset the node Y. After the transistors GS1 and GS2 are turned off, the reset level of the node Y is read out.

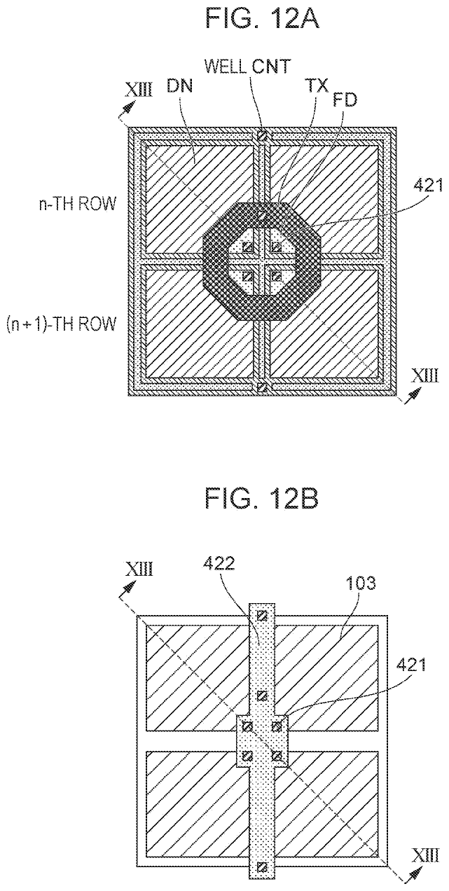

FIGS. 12A and 12B are plan views of the photoelectric conversion apparatus according to the present embodiment. FIG. 12A illustrates a plan view of the first substrate, and FIG. 12B illustrates a plan view of the second substrate. FIGS. 12A and 12B correspond to FIGS. 5A and 5B of the first embodiment.

The photoelectric conversion apparatus illustrated in FIG. 12B differs from the photoelectric conversion apparatus illustrated in FIG. 5B in that the signal processing unit 103 illustrated in FIG. 12B includes elements included in the circuit provided in the stage after the amplification transistor SF.

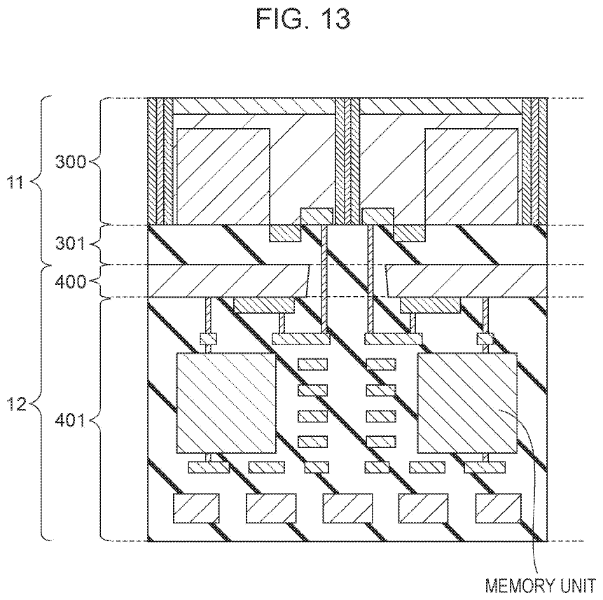

FIG. 13 is a cross-sectional view of the photoelectric conversion apparatus according to the present embodiment. This cross-sectional view illustrates a cross section taken along XIII-XIII of FIGS. 12A and 12B. This photoelectric conversion apparatus differs from the photoelectric conversion apparatus illustrated in the first embodiment in that the second wiring layer 401 is provided with memory units. Two capacitors are required for each signal processing unit 103 to realize this configuration. In FIG. 13, the two memory units are represented as one block.

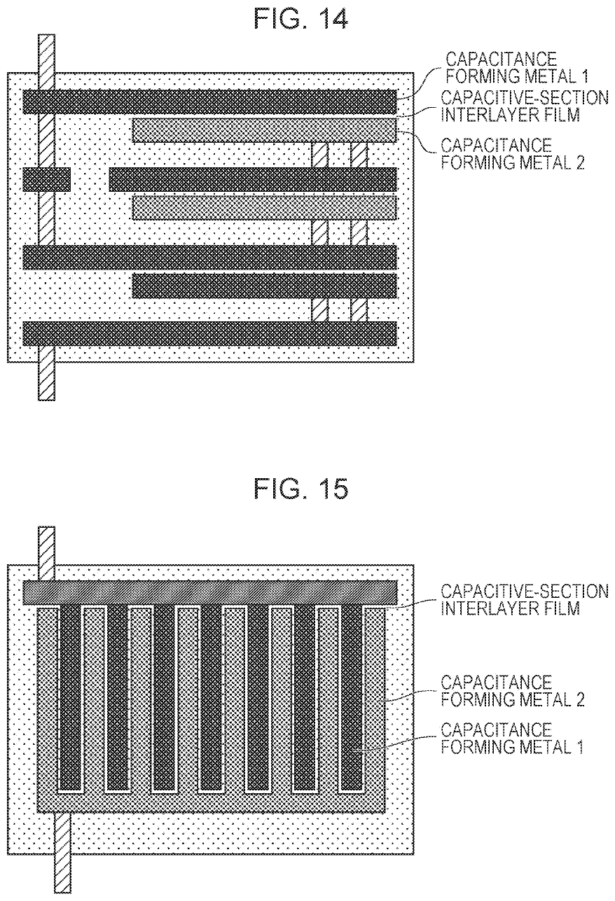

FIG. 14 illustrates a cross-sectional view of an example of the structure of each memory unit. The memory unit may be a metal-insulator-metal (MIM) capacitor, for example. The MIM capacitor is formed using a plurality of capacitance forming metals. The material of the capacitance forming metals may be the same as or different from that of the wiring lines. A capacitive-section interlayer film can be an insulator such as SiO or a dielectric. High-k materials may be used because the higher the dielectric constant of the capacitive-section interlayer film, the greater the capacitance. Examples of high-k materials include, for example, metal oxides such as hafnium oxide (HfO₂), zirconium oxide (ZrO₂), titanium oxide (TiO₂), aluminum oxide (Al₂O₃), and their silicates or aluminates. The capacitive-section interlayer film may include a metal nitride oxide or its silicate or aluminate. Examples of the metal nitride oxide include aluminum oxynitride (AlON), zirconium oxynitride (ZrON), hafnium oxynitride (HfON), lanthanum oxynitride (LaON), and yttrium oxynitride (YON).

FIG. 15 illustrates a cross-sectional view of another example of the structure of each memory unit different from that illustrated in FIG. 14. In the configuration illustrated in FIG. 15, a capacitor is formed by a capacitance forming metal 1 like a pillar and a capacitance forming metal 2 facing the capacitance forming metal 1 with a capacitive-section interlayer film interposed therebetween. Since capacitance formation can be performed three-dimensionally, the capacitance can be increased. A larger memory capacity is advantageous in terms of the S/N ratio of signal to reset noise in the memory unit.

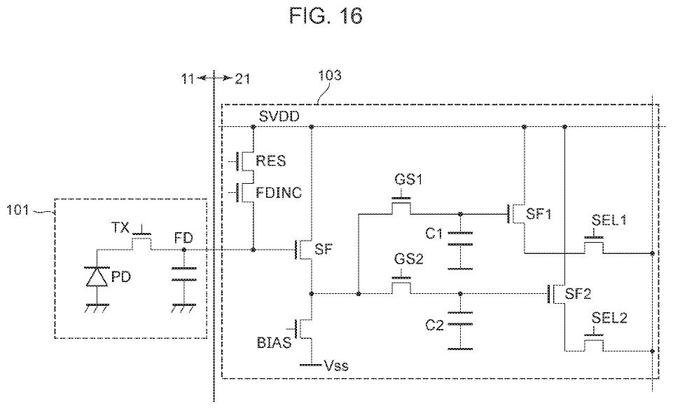

FIG. 16 illustrates a modification example of a circuit configuration of the pixel 101. One difference from the circuit illustrated in FIG. 11 is that the memory provided in the stage after the amplification transistor SF is divided into two systems. A second transistor SF2 and a second selection transistor SEL2 are also added in accordance with division of the memory. Signal charge generated in the photoelectric conversion unit PD is transferred to the floating diffusion FD by the first transfer transistor and is input to the gate of the first amplification transistor SF. The source or drain of the first amplification transistor SF is connected to a first signal holding unit C1 and the gate of a third amplification transistor SF1. The source or drain of the amplification transistor SF is connected to a second signal holding unit C2 and the gate of a fourth amplification transistor SF2.

In the circuit with this configuration, a method can be used in which the N and S signals of the floating diffusion FD are stored, in a respective manner, in the memory units connected in parallel and read out in a sequential manner.

In the circuit with the configuration illustrated in FIG. 11, signal holding is achieved by capacitive division using the two capacitors C1 and C2. Thus, this causes a problem in that the sampling gain would be 0.5 times higher in a usual capacitance configuration. When the gain is 0.5 times higher, the amplitude of a signal of the photoelectric conversion result is reduced by half, resulting in a reduction in the S/N ratio of the signal to noise of the column amplifier and AD converter in the subsequent stage. Generally, image quality (ImageQuality: IQ) is thus reduced.

In contrast, the circuit configuration illustrated in FIG. 16 allows the sampling gain to be set to almost 1. Image quality is thus improved compared to a case where the circuit configuration illustrated in FIG. 11 is used. However, with this configuration, signal readout is performed via different readout paths, one of which passes through the third amplification transistor SF1 and the other of which passes through the fourth amplification transistor SF2. Thus, for example, characteristic variations between the third and fourth amplification transistors SF1 and SF2 cannot be canceled, and this may cause fixed pattern noise to deteriorate. In addition, the reset noise component for each electric charge transfer cannot be removed.

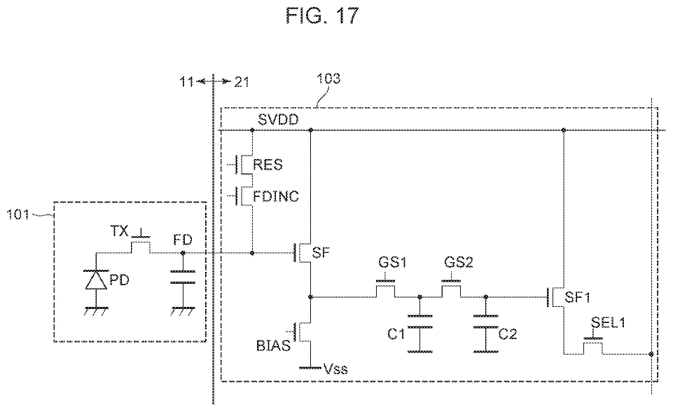

FIG. 17 illustrates another modification example of the circuit configuration of the pixel 101. FIG. 17 differs from FIGS. 11 and 16 in terms of the capacitance and the arrangement of the gates of transistors. In FIG. 17, the transistors GS1 and GS2 and the memories C1 and C2 are connected in series in an alternate manner between the output terminal of the amplification transistor SF and the transistor SF1.

In this configuration, similarly to as in the configuration illustrated in FIG. 11, S and N signals can be read out in one readout system. Thus, deterioration of fixed pattern noise due to element characteristics does not occur. Reset noise in the memories C1 and C2 can also be removed.

In the circuit configuration according to the present embodiment, for example, the following driving is assumed.

Description of the operation will be started from the point where the floating diffusion FD, the memory C1, and the memory C2 are reset. The transistors GS1 and GS2 are turned on, and the N signal at a reset level is read out and written into the memory C2.

The transfer transistor TX is turned on, and electric charge is transferred from the photodiode PD.

The transistor GS1 is turned off, the transistor GS2 is turned on, and the (S+N) signal is read out and written into the memory C1. After reading out the N signal to a correlated double sampling (CDS) circuit positioned in the subsequent stage, the transistor GS2 is turned on to distribute electric charge. By reading (S/2+N) to the CDS circuit and subtracting the N signal from (S/2+N), an S/2 signal whose pixel reset noise has been removed can be obtained.

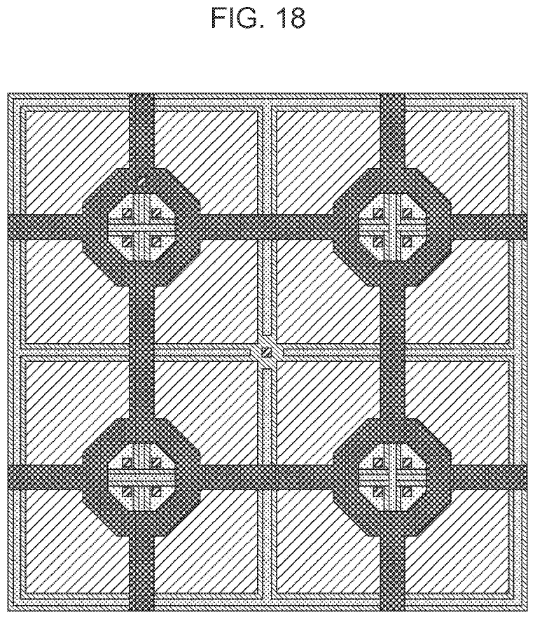

FIG. 18 is a modification example of a plan view of the first substrate of the photoelectric conversion apparatus according to the present embodiment.

The gates of the transfer transistors TX, which are shared in units of every two rows and two columns among the pixels 101, are more extensively connected as a POL wiring line. For example, all pixels in the pixel array may be connected and driven simultaneously. The number of through-electrodes can be further reduced.

### Fourth Embodiment

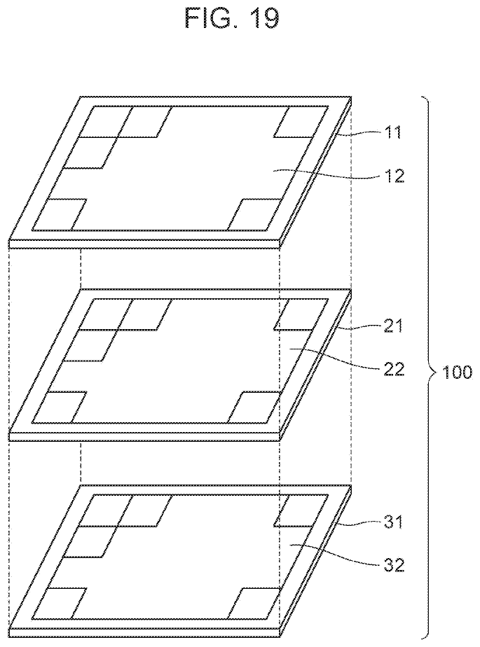

A photoelectric conversion apparatus according to the present embodiment will be described using FIGS. 19 to 29C. Description common to the first embodiment will be omitted, and points that differ from the third embodiment will be mainly described.

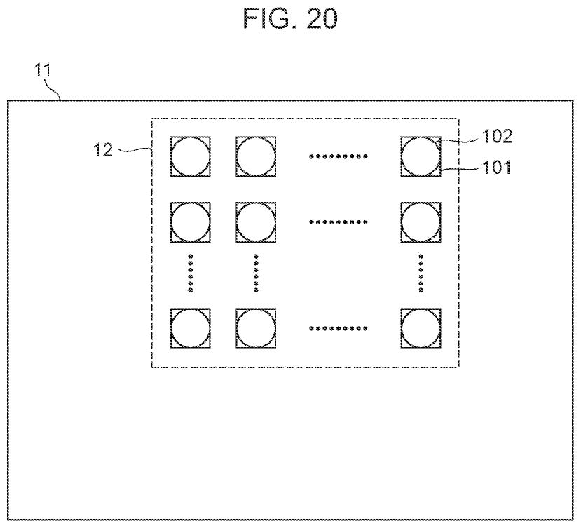

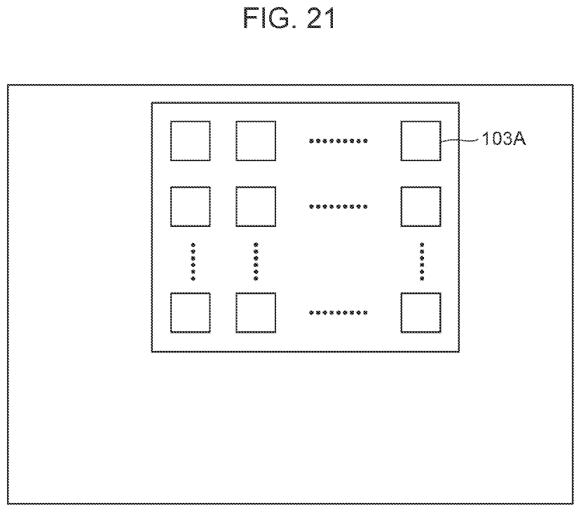

FIG. 19 is a diagram illustrating the configuration of a photoelectric conversion apparatus 100 of a multilayer type according to a fourth embodiment of the present disclosure. FIG. 20 is a diagram of the configuration of the sensor substrate 11. FIG. 21 is a diagram of the configuration of the circuit substrate 21.

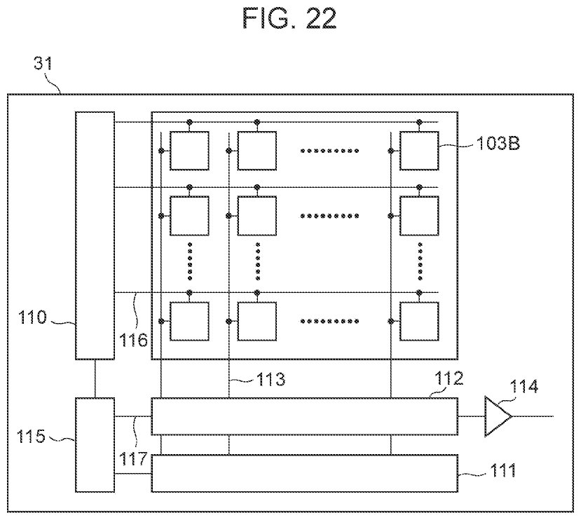

FIG. 22 is a diagram of the configuration of a second circuit substrate 31. The photoelectric conversion apparatus 100 is formed by stacking and electrically connecting three substrates, which are the sensor substrate 11, the circuit substrate 21, and the second circuit substrate 31. Similarly to the sensor substrate 11 and the circuit substrate 21, the second circuit substrate 31 has a front surface (a fifth plane) that is in contact with a wiring layer and a rear surface (a sixth plane) facing the front surface.

In the following, the sensor substrate 11, the circuit substrate 21, and the second circuit substrate 31 will be described as chips obtained by dicing; however, the sensor substrate 11, the circuit substrate 21, and the second circuit substrate 31 are not limited to such chips. For example, each substrate may be a wafer. The individual substrates may be stacked one on top of the other in a wafer state and then be subjected to dicing. Alternatively, the individual substrates may also be divided into chips, and chips may be staked one on top of the other and joined to each other. The sensor substrate 11 may also be called the first substrate 11, the circuit substrate 21 may also be called the second substrate 21, and the second circuit substrate 31 may also be called a third substrate 31 or a third component.

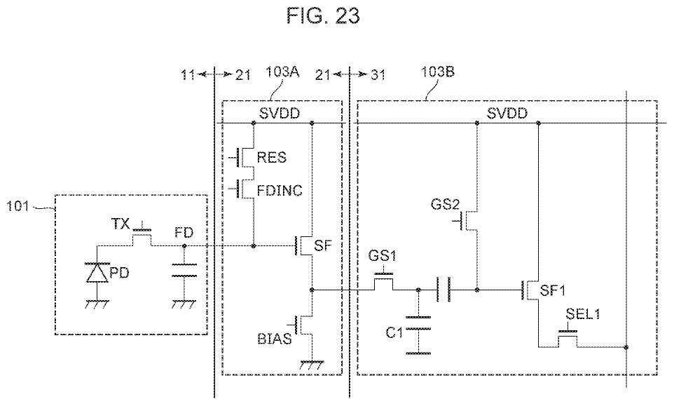

The fourth embodiment differs from the third embodiment in that the second circuit substrate 31 and a second circuit region 32 are added. The signal processing sections 103 are arranged across two substrates, which are the circuit substrate 21 and the second circuit substrate 31. The signal processing units arranged in or on the circuit substrate 21 are treated as signal processing units 103A, and the signal processing units arranged in or on the second circuit substrate 31 are treated as signal processing units 103B. FIG. 23 is an example of a block diagram including equivalent circuits of elements arranged in or on the first to third substrates. The signal processing unit 103A includes a reset transistor RES, a transistor FDINC, and an amplification transistor SF. The signal processing unit 103B includes transistors GS1, GS2, and SF1, and a selection transistor SEL1.

The photoelectric conversion elements 102 illustrated in FIG. 20 and the signal processing units 103A illustrated in FIG. 21 are electrically connected by connection wiring lines provided for the respective pixels. Furthermore, in the present embodiment, the signal processing units 103A illustrated in FIG. 21 and the signal processing units 103B illustrated in FIG. 22 are electrically connected by connection wiring lines provided for the respective pixels.

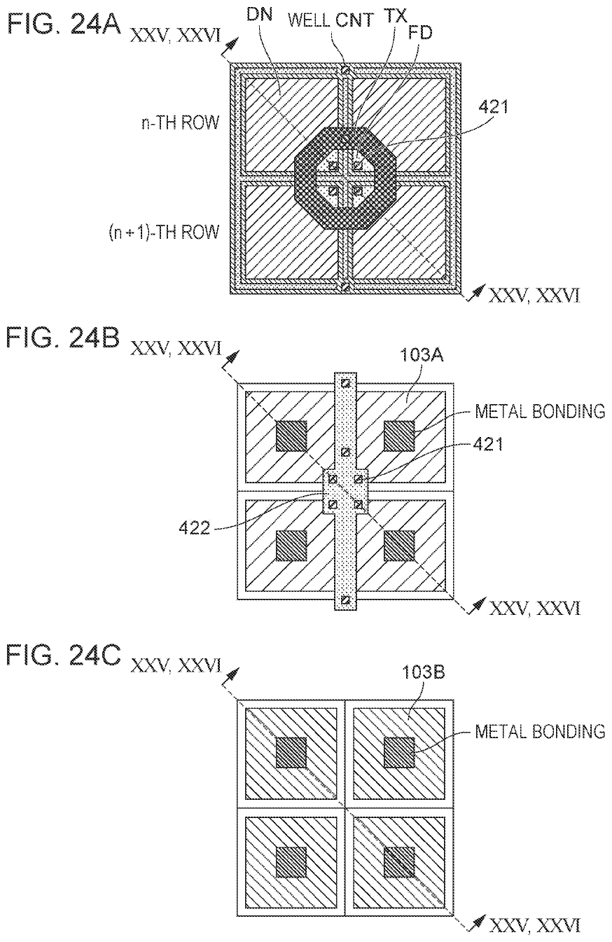

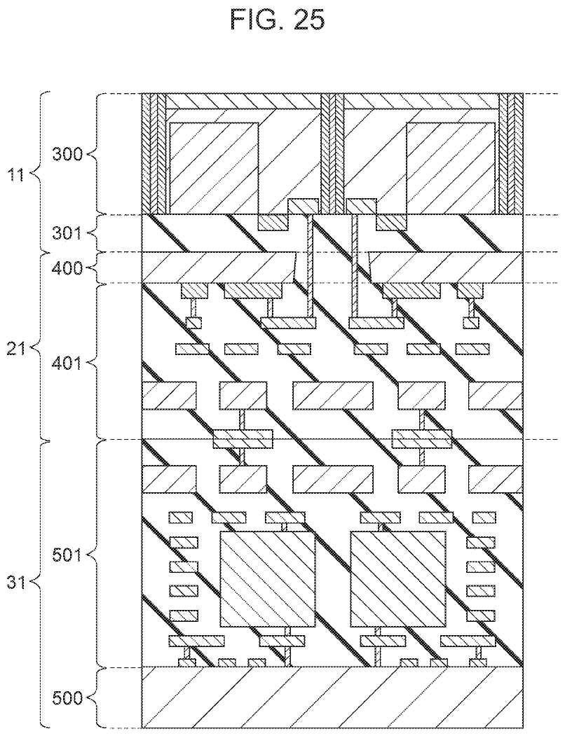

FIGS. 24A, 24B, and 24C are plan schematic diagrams of the first substrate 11, the second substrate 21, and the third substrate 31. FIG. 25 is a cross-section schematic diagram taken along XXV-XXV of FIGS. 24A to 24C. The third substrate 31 includes the third semiconductor layer 500 (a third semiconductor substrate) and the third wiring layer 501. The first substrate 11 and the second substrate 21 are connected so that the front surface of the first semiconductor layer and the rear surface of the second semiconductor layer face each other, similarly to as in the first embodiment. The second substrate 21 and the third substrate 31 are connected so that the front surface of the second semiconductor layer and the front surface of the third semiconductor layer face each other. This connection is made using metal bonding (hybrid bonding) technology, for example, using Cu or Au as a bonding portion.

Normally, when hybrid bonding is used to bond wiring layers facing each other, it is difficult to electrically connect yet another semiconductor layer on a pixel-by-pixel basis. However, by using the configuration illustrated in the present embodiment, it is possible to achieve three-layer stacking that is obtained by electrically connecting the three layers on a pixel-by-pixel basis. With a structure in which the three semiconductor layers are stacked, the area of arrangement for the signal processing circuit can be increased, so that higher functionality can be achieved.

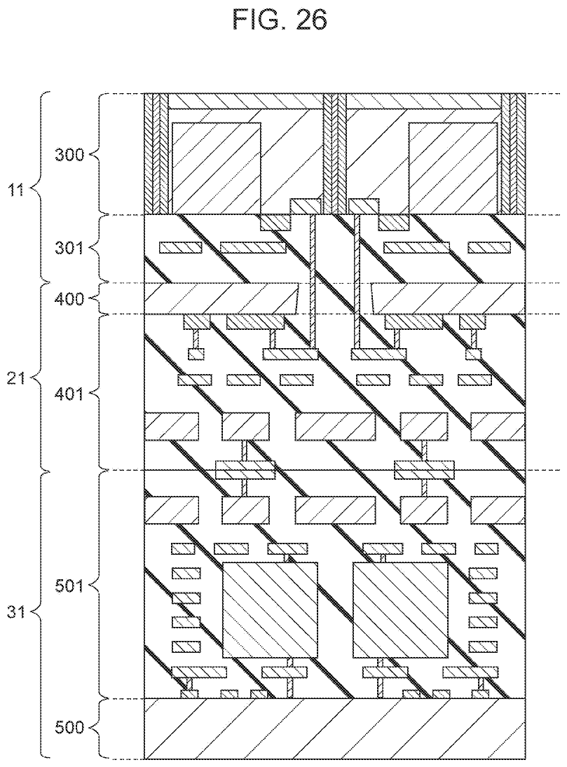

FIG. 26 is a cross-sectional schematic view of a modification example of the photoelectric conversion apparatus according to the disclosure, the view being taken along XXVI-XXVI of FIGS. 24A to 24C.

In the photoelectric conversion apparatus illustrated in FIG. 25, a metal wiring line is not provided between the first semiconductor layer 300 and the second semiconductor layer 400. However, as illustrated in FIG. 26, wiring lines may be arranged in the first wiring layer 301 between the first semiconductor layer 300 and the second semiconductor layer 400, and the transfer transistors TX of a plurality of pixels 101 and elements on the second semiconductor layer 400 may be connected by wiring lines arranged in the first wiring layer 301. In this case, it is not always necessary to share the gates of the transfer transistors TX among the plurality of pixels 101.

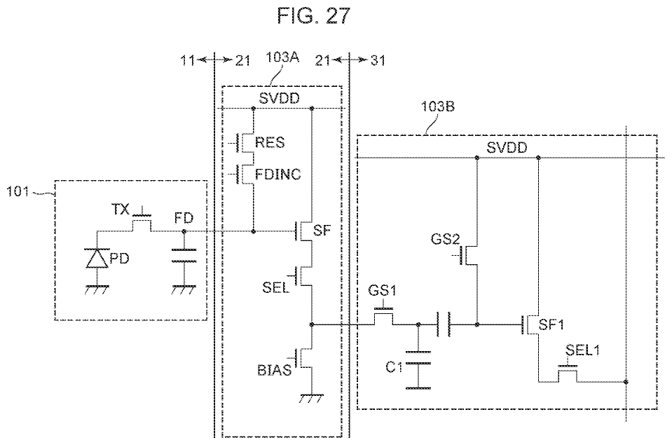

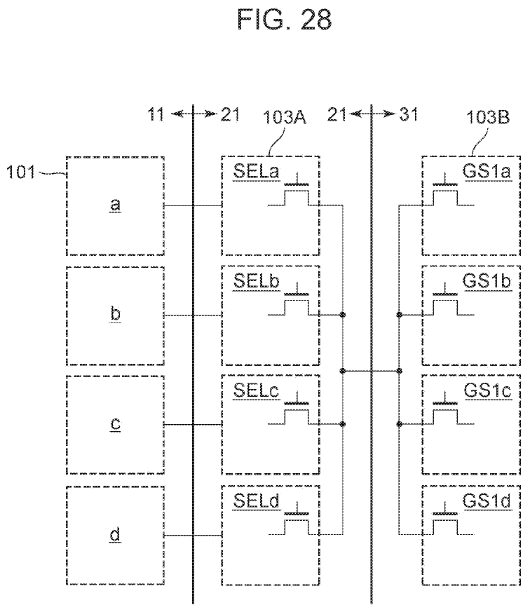

A further modification example of the configuration of the photoelectric conversion apparatus according to the present embodiment is illustrated using FIGS. 27 to 29C. FIG. 27 illustrates a modification example of the configuration of the pixel 101. The circuit configuration illustrated in FIG. 27 differs from that illustrated in FIG. 23 in that the signal processing unit 103A includes a selection transistor SEL. FIG. 28 is a circuit block diagram, and each pixel 101, each signal processing unit 103A and each signal processing unit 103B correspond to those in the circuit diagram illustrated in FIG. 27. The four pixels 101 are connected to independent signal processing units 103A in a respective manner, and the four pixels 101 share a wiring line from the signal processing units 103A to the signal processing units 103B. This configuration reduces the number of metal bondings, and this is advantageous for miniaturization.

Note that, to ensure the global shutter function of transferring signals at the same time, it is sufficient that the transfer transistors TX operate collectively and the signals be transferred to the floating diffusions FD. In other words, the timings at which the SF outputs after transfer are transferred to the memory units via the gates of the transistors GS1 do not have to match. It is sufficient that the selection transistors SEL and the gates of the transistors GS1 corresponding to the four pixels 101 be operated in the order of a, b, c, and d illustrated in FIG. 28, and transfer to the memory units be performed.

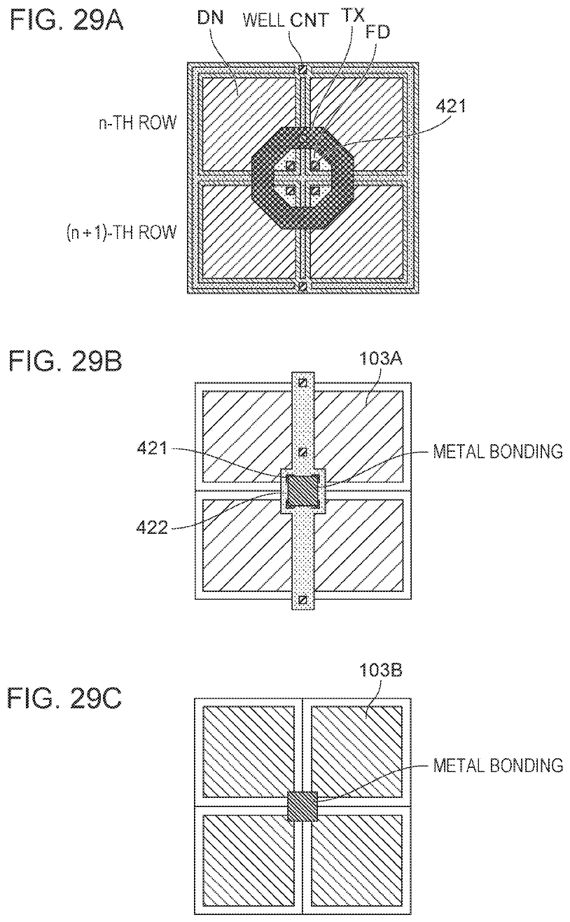

FIGS. 29A to 29C are plan views corresponding to the configurations illustrated in FIGS. 27 and 28. For the second substrate 21 and the third substrate 31, four pixels in two rows and two columns are connected by common metal bonding.

### Fifth Embodiment

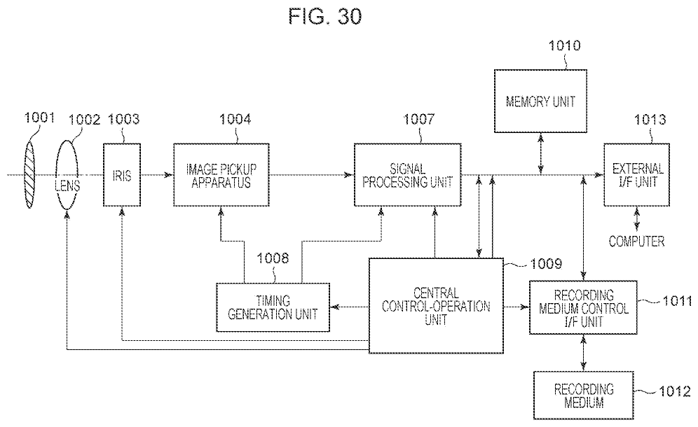

A photoelectric conversion system according to the present embodiment will be described using FIG. 30. FIG. 30 is a block diagram illustrating a schematic configuration of the photoelectric conversion system according to the present embodiment.

The photoelectric conversion apparatuses described in the first to fourth embodiments described above can be applied to various types of photoelectric conversion systems. Examples of the photoelectric conversion systems to which the photoelectric conversion apparatuses described in the first to fourth embodiments described above can be applied include digital still cameras, digital camcorders, surveillance cameras, copiers, fax machines, mobile phones, vehicle-mounted cameras, and observation satellites. The examples of the photoelectric conversion systems also include a camera module having an optical system such as a lens and an image pickup apparatus. FIG. 29 illustrates a block diagram of a digital camera as an example from among these examples.

The photoelectric conversion system illustrated in FIG. 30 includes an image pickup apparatus 1004 as an example of the photoelectric conversion apparatuses and a lens 1002 for causing the image pickup apparatus 1004 to form an optical image of a subject. The photoelectric conversion system further includes an iris 1003 for changing the amount of light passing through the lens 1002 and a barrier 1001 for protecting the lens 1002. The lens 1002 and the iris 1003 are an optical system for concentrating light onto the image pickup apparatus 1004. The image pickup apparatus 1004 is any one of the photoelectric conversion apparatuses according to the embodiments described above and converts the optical image formed by the lens 1002 into an electric signal.

The photoelectric conversion system includes a signal processing unit 1007, which is an image generation unit configured to generate an image by performing processing on an output signal output from the image pickup apparatus 1004. The signal processing unit 1007 performs an operation in which various types of correction or compression are performed as needed to output image data. The signal processing unit 1007 may be formed in or on a semiconductor substrate provided with the image pickup apparatus 1004 or may be formed in or on another semiconductor substrate different from the semiconductor substrate provided with the image pickup apparatus 1004.

The photoelectric conversion system further includes a memory unit 1010 for temporarily storing image data and an external interface (I/F) unit 1013 for communicating with an external computer or the like. Furthermore, the photoelectric conversion system includes a recording medium 1012 such as a semiconductor memory for recording or reading out captured image data and a recording medium control I/F unit 1011 for recording data in or reading out data from the recording medium 1012. Note that the recording medium 1012 may be built in or detachable from the photoelectric conversion system.

Furthermore, the photoelectric conversion system includes a central control-operation unit 1009, which controls various types of arithmetic operations and the entire digital still camera, and a timing generation unit 1008, which outputs various types of timing signals to the image pickup apparatus 1004 and the signal processing unit 1007. In this case, a timing signal and the like may be input from the outside. It is sufficient that the photoelectric conversion system include at least the image pickup apparatus 1004 and the signal processing unit 1007, which processes an output signal output from the image pickup apparatus 1004.

The image pickup apparatus 1004 outputs an image pickup signal to the signal processing unit 1007. The signal processing unit 1007 performs certain signal processing on the image pickup signal output from the image pickup apparatus 1004 to output image data. The signal processing unit 1007 generates an image using the image pickup signal output from the image pickup apparatus 1004.

In this manner, according to the present embodiment, the photoelectric conversion system can be realized to which any one of the photoelectric conversion apparatuses (image pickup apparatuses) according to the embodiments described above.

### Sixth Embodiment

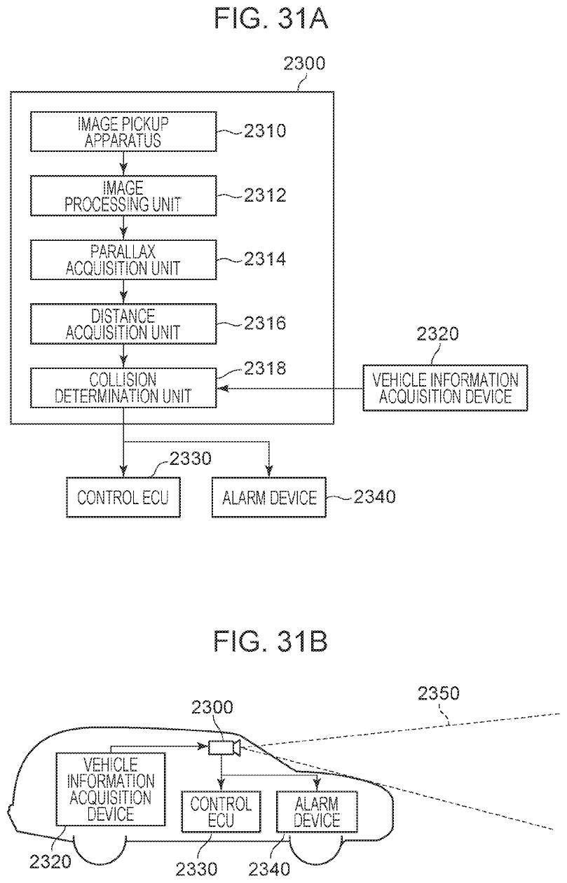

A photoelectric conversion system and a moving object according to the present embodiment will be described using FIGS. 31A and 31B. FIGS. 31A and 31B are diagrams illustrating the configurations of the photoelectric conversion system and the moving object according to the present embodiment.

FIG. 31A illustrates an example of the photoelectric conversion system regarding a vehicle-mounted camera. A photoelectric conversion system 2300 has an image pickup apparatus 2310. The image pickup apparatus 2310 is any one of the photoelectric conversion apparatuses described in the above-described embodiments. The photoelectric conversion system 2300 has an image processing unit 2312, which performs image processing on a plurality of pieces of image data acquired by the image pickup apparatus 2310. The photoelectric conversion system 2300 also has a parallax acquisition unit 2314, which calculates parallax (a phase difference of a parallax image) from a plurality of pieces of image data acquired by the image processing unit 2312. Furthermore, the photoelectric conversion system 2300 has a distance acquisition unit 2316 and a collision determination unit 2318. The distance acquisition unit 2316 calculates the distance to a target object on the basis of the calculated parallax. The collision determination unit 2318 determines on the basis of the calculated distance whether there are chances of a collision. In this case, the parallax acquisition unit 2314 or the distance acquisition unit 2316 is an example of a distance information acquisition unit configured to acquire information regarding the distance to the target object (hereinafter referred to as distance information). That is, the distance information is information regarding parallax, the amount of defocusing, the distance to the target object, and so forth. The collision determination unit 2318 may determine chances of a collision using any information included in the distance information. The distance information acquisition unit may be realized by a hardware device designed in a dedicated manner or a software module.

The distance information acquisition unit may also be realized by, for example, a field-programmable gate array (FPGA) or an application-specific integrated circuit (ASIC) or may also be realized by a combination of an FPGA and an ASIC.

The photoelectric conversion system 2300 is connected to a vehicle information acquisition device 2320 and can acquire vehicle information such as a vehicle speed, a yaw rate, and a steering angle. Moreover, a control engine control unit (ECU) 2330 is connected to the photoelectric conversion system 2300. The control ECU 2330 is a controller that outputs, on the basis of a determination result from the collision determination unit 2318, a control signal for causing the vehicle to generate a braking force. Moreover, the photoelectric conversion system 2300 is also connected to an alarm device 2340, which alerts the driver on the basis of a determination result from the collision determination unit 2318. For example, in a case where the chances of a collision are high based on a determination result from the collision determination unit 2318, the control ECU 2330 performs vehicle control to avoid a collision or reduce damage by braking, releasing the accelerator, controlling the engine output, or the like. The alarm device 2340 alerts the user by going off an alarm such as certain sound, displaying alarm information on the screen of, for example, a car navigation system, or vibrating their seat belt or the steering wheel.

In the present embodiment, images around the vehicle, for example, images of views in front of or behind the vehicle are captured by the photoelectric conversion system 2300. FIG. 31B illustrates the photoelectric conversion system for a case where images of views in front of the vehicle (an image pickup area 2350) are captured. The vehicle information acquisition device 2320 sends a command to the photoelectric conversion system 2300 or the image pickup apparatus 2310. With such a configuration, the accuracy of distance measurement can be more greatly improved.

In the above, an example has been described in which control for preventing the vehicle from colliding with other vehicles. However, the photoelectric conversion system 2300 can also be applied to perform, for example, control under which the vehicle drives autonomously so as to follow other vehicles or control under which the vehicle drives autonomously so as not to drive out of the lane. Furthermore, the photoelectric conversion system 2300 can be applied not only to vehicles such as cars but also to, for example, moving objects (moving apparatuses) such as vessels, airplanes, or industrial robots. In addition, the photoelectric conversion system 2300 can be applied not only to moving objects but also to a wide range of apparatuses using object recognition such as an intelligent transportation system (ITS).

### Seventh Embodiment

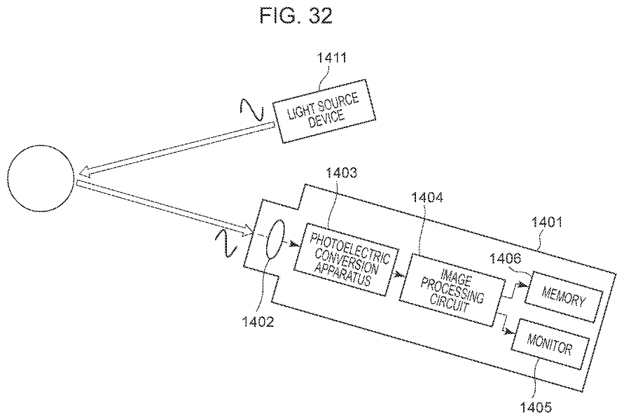

A photoelectric conversion system according to the present embodiment will be described using FIG. 32. FIG. 32 is a block diagram illustrating an example of the configuration of a distance image sensor, which is a photoelectric conversion system

As illustrated in FIG. 32, a distance image sensor 1401 includes an optical system 1402, a photoelectric conversion apparatus 1403, an image processing circuit 1404, a monitor 1405, and a memory 1406. The distance image sensor 1401 receives light emitted from a light source device 1411 to a subject and reflected by the surface of the subject (modulated light or pulsed light) and consequently can acquire a distance image corresponding to the distance to the subject.

The optical system 1402 includes one or more lenses. The optical system 1402 guides image light (incident light) from the subject to the photoelectric conversion apparatus 1403, and causes an image to be formed on a light receiving surface (a sensor unit) of the photoelectric conversion apparatus 1403.

As the photoelectric conversion apparatus 1403, any one of the photoelectric conversion apparatuses described in the individual embodiments described above is used. A distance signal representing a distance obtained from a light reception signal and output from the photoelectric conversion apparatus 1403 is supplied to the image processing circuit 1404.

The image processing circuit 1404 performs image processing in which a distance image is constructed on the basis of the distance signal supplied from the photoelectric conversion apparatus 1403. The distance image (image data) obtained as a result of the image processing is supplied to and displayed on the monitor 1405 or is supplied to and stored (recorded) in the memory 1406.

In the distance image sensor 1401 configured in this manner, the characteristics of pixels are improved by using one of the photoelectric conversion apparatuses described above and consequently, for example, a more accurate distance image can be acquired.

### Eighth Embodiment

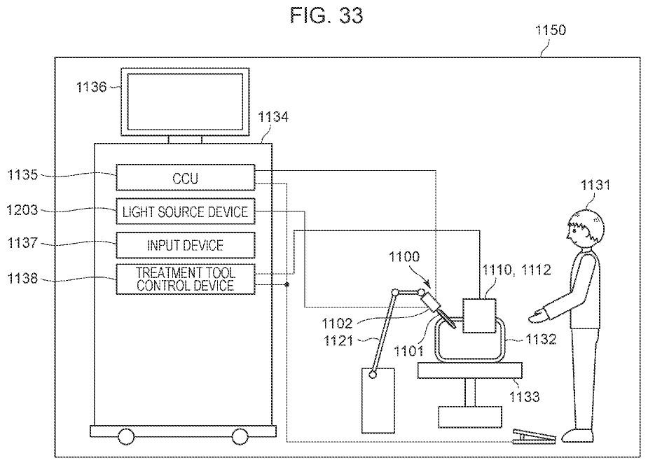

A photoelectric conversion system according to the present embodiment will be described using FIG. 33. FIG. 33 is a diagram illustrating an example of a schematic configuration of an endoscopic operation system, which is a photoelectric conversion system according to the present embodiment.

FIG. 33 illustrates a situation in which a practitioner (a doctor) 1131 is performing a surgical operation on a patient 1132 on a patient bed 1133 by using an endoscopic operation system 1150. As illustrated in FIG. 33, the endoscopic operation system 1150 includes an endoscope 1100, a surgical tool 1110, and a cart 1134, on which various types of devices for endoscopic operations are mounted.

The endoscope 1100 includes a lens tube 1101 and a camera head 1102. A portion of the lens tube 1101 starting from its leading edge and having a predetermined length is inserted into a body cavity of the patient 1132. The camera head 1102 is connected to a base end of the lens tube 1101. In the illustrated example, the endoscope 1100 is formed as a rigid scope including the lens tube 1101, which is rigid; however, the endoscope 1100 may be formed as a so-called flexible scope having a flexible lens tube.

The leading edge of the lens tube 1101 is provided with an opening in which an objective lens is embedded. The endoscope 1100 is connected to a light source device 1203. Light generated by the light source device 1203 is guided to the leading edge of the lens tube 1101 along a light guide extended in the lens tube 1101. Light guided to the leading edge of the lens tube 1101 is emitted toward an observation target in the body cavity of the patient 1132 through the objective lens. Note that the endoscope 1100 may be a direct-viewing endoscope, an oblique-viewing endoscope, or a side-viewing endoscope.

The camera head 1102 includes an optical system and a photoelectric conversion apparatus. Reflected light (observation light) from the observation target is concentrated by the optical system onto the photoelectric conversion apparatus. The observation light is photoelectrically converted by the photoelectric conversion apparatus, and an electric signal corresponding to the observation light, that is, an image signal corresponding to an observation image is generated. As the photoelectric conversion apparatus, any one of the photoelectric conversion apparatuses described in the individual embodiments described above can be used. The image signal is transmitted as RAW data to a camera control unit (CCU) 1135.

The CCU 1135 includes, for example, a central processing unit (CPU) and a graphics processing unit (GPU), and performs central control on operations of the endoscope 1100 and a display device 1136. Furthermore, the CCU 1135 receives an image signal from the camera head 1102, and performs, on the image signal, various types of image processing for displaying an image based on the image signal such as development processing (demosaicing) or the like.

The display device 1136 displays, under control performed by the CCU 1135, the image based on the image signal on which image processing is performed by the CCU 1135.

The light source device 1203 includes, for example, a light source such as a light-emitting diode (LED) and supplies, to the endoscope 1100, illumination light to be used when an image of a surgical target or the like is captured.

An input device 1137 is an input interface for the endoscopic operation system 1150. The user can input various types of information or commands to the endoscopic operation system 1150 through the input device 1137.

A treatment tool control device 1138 controls driving of an energy treatment tool 1112 for ablating or dissecting tissue, closing a blood vessel, or the like.

The light source device 1203 supplies, to the endoscope 1100, illumination light to be used when an image of a surgical target is captured. The light source device 1203 includes a white light source formed by, for example, LEDs, laser light sources, or a combination of LEDs and laser light sources. In a case where the white light source is formed by a combination of RGB laser light sources, the output intensity and the output timing of each color (each wavelength) can be controlled with high accuracy, and thus the white balance of a captured image can be adjusted by the light source device 1203. Moreover, in this case, by irradiating an observation target with laser light from each of the RGB laser light sources in a time division manner and controlling driving of an image sensor of the camera head 1102 in synchronization with the irradiation timing, images corresponding to R, G, and B in a respective manner can be captured in a time division manner. With the method, the image sensor can capture color images without being provided with color filters.

Driving of the light source device 1203 may be controlled such that the intensity of output light is changed every certain time period. Images are acquired in a time division manner by controlling driving of the image sensor of the camera head 1102 in synchronization with the timing at which the intensity of the light is changed, and the images are combined. As a result, high dynamic range images without so-called crushed shadows and blown highlights can be generated.

The light source device 1203 may also be configured to be able to supply light having a predetermined wavelength band corresponding to special light observation. In special light observation, for example, the wavelength dependence of light absorption in body tissue is used. Specifically, by performing irradiation with light of a narrower band than the illumination light used at the time of a normal observation (that is, white light), images of certain tissue such as a blood vessel in a mucosal surface layer can be captured with high contrast.

Alternatively, in special light observation, fluorescence observation may be performed in which an image is obtained using fluorescence generated by excitation light irradiation. In fluorescence observation, for example, body tissue is irradiated with excitation light, and fluorescence from the body tissue can be observed. Alternatively, in fluorescence observation, a reagent such as indocyanine green (ICG) is locally injected to body tissue, and the body tissue is irradiated with excitation light corresponding to the fluorescence wavelength of the reagent, so that a fluorescence image can be obtained. The light source device 1203 may be configured to be able to supply at least one out of light of a narrow band and excitation light that correspond to such special light observation.

### Ninth Embodiment

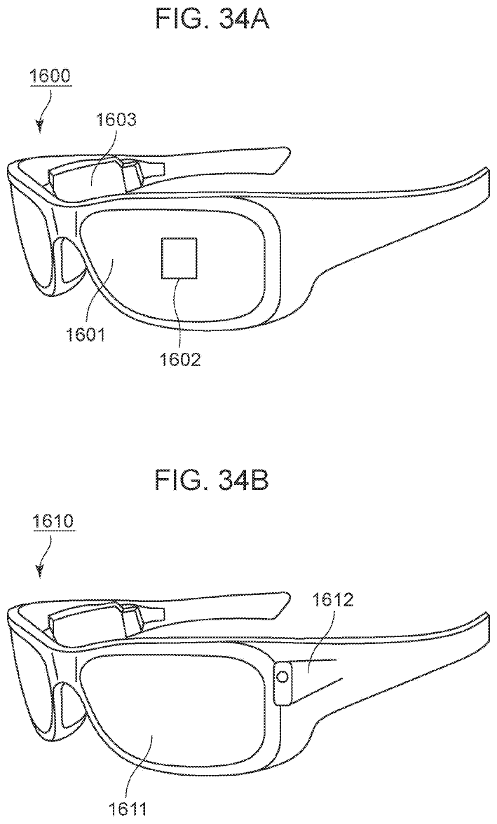

A photoelectric conversion system according to the present embodiment will be described using FIGS. 34A and 34B. FIG. 34A illustrates glasses 1600 (smart glasses), which constitute a photoelectric conversion system. The glasses 1600 have a photoelectric conversion apparatus 1602. The photoelectric conversion apparatus 1602 is one of the photoelectric conversion apparatuses described in the individual embodiments described above. A display device including a luminescent device such as an organic light-emitting diode (OLED) or a light-emitting diode (LED) may be provided on the back side of a lens 1601. There may be one photoelectric conversion apparatus 1602 or more. Alternatively, a plurality of types of photoelectric conversion apparatuses may be combined and used. The photoelectric conversion apparatus 1602 does not have to be arranged at the position illustrated in FIG. 34A.

The glasses 1600 further have a control device 1603. The control device 1603 functions as a power source that supplies power to the photoelectric conversion apparatus 1602 and the display device described above. The control device 1603 controls the operation of the photoelectric conversion apparatus 1602 and the display device. In the lens 1601, an optical system is formed that concentrate light onto the photoelectric conversion apparatus 1602.

FIG. 34B illustrates glasses 1610 (smart glasses) according to one application. The glasses 1610 have a control device 1612. The control device 1612 includes a photoelectric conversion apparatus corresponding to the photoelectric conversion apparatus 1602 and a display device. In a lens 1611, an optical system is formed that projects light emitted from the photoelectric conversion apparatus and the display device included in the control device 1612. An image is projected onto the lens 1611. The control device 1612 functions as a power source that supplies power to the photoelectric conversion apparatus and the display device, and controls the operation of the photoelectric conversion apparatus and the display device. The control device 1612 may have a line-of-sight detection unit configured to detect the line of sight of the wearer. Infrared rays may be used to detect the line of sight of the wearer. An infrared-emitting unit emits infrared light to an eyeball of the user gazing at a displayed image. An image of their eyeball is captured by an image capturing unit, which has a light reception element, detecting reflected light of the emitted infrared light from their eyeball. A decrease in the quality of images is reduced by provision of a reduction unit that reduces the amount of light from the infrared-emitting unit to a display unit in a plan view.

The line of sight of the user to the displayed image is detected from the image of their eyeball captured through image capturing using infrared light. A freely chosen known method can be applied to line-of-sight detection using a captured image of their eyeball. As an example, a line-of-sight detection method based on Purkinje images generated by reflected illumination light from the user's cornea can be used.

More specifically, line-of-sight detection processing based on a pupil-corneal reflection method is performed. The line of sight of the user is detected by calculating, using a pupil-corneal reflection method, a line-of-sight vector representing the orientation of their eyeball (a rotation angle) on the basis of an image of their pupil and Purkinje images included in a captured image of their eyeball.

The display device according to the present embodiment has a photoelectric conversion apparatus having a light reception element, and may control an image displayed on the display device on the basis of information regarding the user's line of sight from the photoelectric conversion apparatus.

Specifically, for the display device, a first line-of-sight region, at which the user gazes, and a second line-of-sight region other than the first line-of-sight region are determined on the basis of the line-of-sight information. The first display region and the second display region may be determined by the control device of the display device. Alternatively, the first display region and the second display region determined by an external control device may be received. In a display region of the display device, the display resolution of the first line-of-sight region may be controlled to be higher than that of the second line-of-sight region. That is, the resolution of the second line-of-sight region may be made lower than that of the first line-of-sight region.

The display region has a first display region and a second display region, which is different from the first display region. A prioritized region may be determined from among the first display region and the second display region on the basis of the line-of-sight information. The first display region and the second display region may be determined by the control device of the display device. Alternatively, the first display region and the second display region determined by an external control device may be received. The resolution of the prioritized region may be controlled to be higher than that of the region other than the prioritized region. That is, the resolution of the region having a relatively low priority may be reduced.

Note that artificial intelligence (AI) may be used to determine the first line-of-sight region or the prioritized region. AI may be a model configured to use an image of a user's eyeball and the direction in which their eyeball in the image actually sees as supervised data and to estimate the angle of the line of sight from an image of a user's eyeball and the distance to a target ahead of the line of sight. The display device, the photoelectric conversion apparatus, or an external device may have an AI program. In a case where an external device has the AI program, the angle of the line of sight of the user and the distance to the target are transferred to the display device through communication.

In a case where display control is performed on the basis of visual recognition and detection, the present embodiment can be applied to smart glasses further having a photoelectric conversion apparatus that captures an outside image. The smart glasses can display, in real time, outside information regarding a captured outside image.

### Modified Embodiments

The present disclosure is not limited to the embodiments described above, and various modifications are possible.

For example, an example obtained by adding part of any one of the embodiments to another one of the embodiments and an example obtained by replacing part of one of the embodiments with part of another one of the embodiments are also included in embodiments of the present disclosure.

Furthermore, the photoelectric conversion systems described in the fifth and sixth embodiments are examples of photoelectric conversion systems to which the photoelectric conversion apparatuses can be applied. The photoelectric conversion systems to which the photoelectric conversion apparatuses according to the present disclosure are applicable are not limited to the configurations illustrated in FIGS. 30 to 31B. The same applies to the ToF system described in the seventh embodiment, the endoscope described in the eighth embodiment, and the smart glasses described in the ninth embodiment.

Note that the embodiments described above are merely specific examples of embodiments for implementing the present disclosure, and the technical scope of the present disclosure should not be interpreted as limited by these embodiments. In other words, the present disclosure can be implemented in various forms without departing from its technical concept or its main features.

According to the present disclosure, the degree of freedom in arranging elements of the second substrate can be improved.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-190917, filed Nov. 30, 2022, which is hereby incorporated by reference herein in its entirety.

What is claimed is:

1. A photoelectric conversion apparatus comprising:
a first component comprising:
a first semiconductor substrate having a first plane and a second plane facing the first plane,
a first photoelectric conversion circuit configured to receive light from the second plane,
a second photoelectric conversion circuit configured to receive light from the second plane,
a floating diffusion,
a first transfer transistor that is provided on a side where the first plane is provided and that is configured to transfer signal charge generated in the first photoelectric conversion circuit to the floating diffusion, and
a second transfer transistor that is provided on the side where the first plane is provided and that is configured to transfer signal charge generated in the second photoelectric conversion circuit to the floating diffusion; and
a second component comprising:
a second semiconductor substrate having a third plane and a fourth plane facing the third plane,
an insulator configured to penetrate through the second semiconductor substrate from the third plane to the fourth plane or from the fourth plane to the third plane,
a first amplification transistor configured to receive a signal via the first transfer transistor, and a second amplification transistor configured to receive a signal via the second transfer transistor, the second component being stacked on the first component,
wherein a polysilicon member that is a gate of the first transfer transistor is a gate of the second transfer transistor, and a through-electrode configured to penetrate through the insulator and the polysilicon member are electrically connected to each other.

2. The photoelectric conversion apparatus according to claim 1,
wherein the first transfer transistor and the second transfer transistor are controlled by a common control signal.

3. The photoelectric conversion apparatus according to claim 2,
wherein the floating diffusion includes a first floating diffusion and a second floating diffusion,
wherein signal charge generated in the first photoelectric conversion circuit is transferred to the first floating diffusion, and
wherein signal charge generated in the second photoelectric conversion circuit is transferred to the second floating diffusion.

4. The photoelectric conversion apparatus according to claim 3,
wherein a source or drain of the first amplification transistor is connected to a first signal holding circuit and a third amplification transistor, and
wherein a source or drain of the second amplification transistor is connected to a second signal holding circuit and a fourth amplification transistor.

5. The photoelectric conversion apparatus according to claim 3,
wherein a source or drain of the first amplification transistor is connected to a first signal holding circuit, a second signal holding circuit, a third amplification transistor, and a fourth amplification transistor.

6. The photoelectric conversion apparatus according to claim 5,
wherein the first signal holding circuit and the second signal holding circuit are connected in parallel.

7. The photoelectric conversion apparatus according to claim 5,
wherein the first signal holding circuit and the second signal holding circuit are connected in series.

8. The photoelectric conversion apparatus according to claim 4,
wherein a control signal controlling the third amplification transistor is different from a control signal controlling the fourth amplification transistor.

9. The photoelectric conversion apparatus according to claim 4, further comprising:
a third component comprising:
a third semiconductor substrate having a fifth plane and a sixth plane facing the fifth plane, and include the first signal holding circuit, the second signal holding circuit, the third amplification transistor, and the fourth amplification transistor.

10. The photoelectric conversion apparatus according to claim 9,
wherein bonding portions that are configured to electrically connect the first component and the second component to each other are smaller in number than bonding portions that are configured to electrically connect the second component and the third component to each other.

11. The photoelectric conversion apparatus according to claim 1,
wherein a voltage is supplied to the first transfer transistor via the second semiconductor substrate.

12. The photoelectric conversion apparatus according to claim 9,
wherein the first component has a first wiring layer at the first plane.

13. The photoelectric conversion apparatus according to claim 1,
wherein a first group of transfer transistors composed of a plurality of transfer transistors including the first transfer transistor is controlled by a first control signal, and
wherein a second group of transfer transistors composed of a plurality of transfer transistors including the second transfer transistor is controlled by the first control signal.

14. The photoelectric conversion apparatus according to claim 13,
wherein a direction in which the plurality of transfer transistors included in the first group of transfer transistors are arranged intersects with a direction in which a plurality of the floating diffusions to which the plurality of transfer transistors included in the first group of transfer transistors is connected in a respective manner, and
wherein the plurality of floating diffusions is smaller in number than the plurality of transfer transistors.

15. The photoelectric conversion apparatus according to claim 14,
wherein either one of the first photoelectric conversion circuit and the second photoelectric conversion circuit is shielded from light.

16. The photoelectric conversion apparatus according to claim 13,
wherein a voltage is supplied to the first transfer transistor via the second semiconductor substrate.

17. The photoelectric conversion apparatus according to claim 13,
wherein the first component has a first wiring layer at the first plane.

18. A photoelectric conversion system comprising:
the photoelectric conversion apparatus according to claim 1; and
a signal processing circuit configured to generate an image using a signal output by the photoelectric conversion apparatus.

19. A moving object including the photoelectric conversion apparatus according to claim 1, the moving object comprising:
a controller configured to control movement of the moving object using a signal output by the photoelectric conversion apparatus.
